(19) United States
(12) Patent Application Publication
(10) Pub. No.: US 2014/0022753 A1
(43) Pub. Date: Jan. 23, 2014

(54) MOUNTING APPARATUS FOR EXPANSION CARDS

(71) Applicant: LI-REN FU, Shenzhen City (CN)

(72) Inventor: LI-REN FU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/600,248

(22) Filed: Aug. 31, 2012

(30) Foreign Application Priority Data
Jul. 19, 2012 (CN) 2012102508211

(51) Int. Cl. H05K 7/14

(52) U.S. Cl. 361/807

(57) ABSTRACT

A mounting apparatus for fixing an expansion card to a chassis includes a mounting plate fixed to a rear end of the chassis, a locating bracket secured to the mounting plate, and a locking member slidably mounted to the locating bracket. The expansion card includes an L-shaped block piece, which includes a block portion abutting the mounting plate, and a coupling portion perpendicularly extending from an end of the block portion, and received in the locating bracket. The locking member includes a pressing arm pressing the coupling portion of the block piece to fix the block piece to the chassis.

### BACKGROUND

1. Technical Field

The present disclosure relates to an apparatus for mounting expansion cards.

2. Description of Related Art

Computer systems require expansion cards to expand functions. An expansion card usually includes a main body electrically connectable to a motherboard in a computer system, and a generally L-shaped block plate installable on a rear plate of the computer system. The block plate is usually installed on the rear plate by screws, which is inconvenient.

### BRIEF DESCRIPTION OF THE DRAWINGS

Many aspects of the present embodiments can be better understood with reference to the following drawings. The components in the drawing are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of a mounting apparatus, an expansion card, and a chassis.

FIG. 2 is similar to FIG. 1 except viewed from another perspective.

FIG. 3 is an enlarged view of a circled portion III of FIG. 1.

FIG. 4 is a partial, enlarged, assembled view of FIG. 1, showing the expansion card being released.

FIG. 5 is an assembled view of FIG. 1.

### DETAILED DESCRIPTION

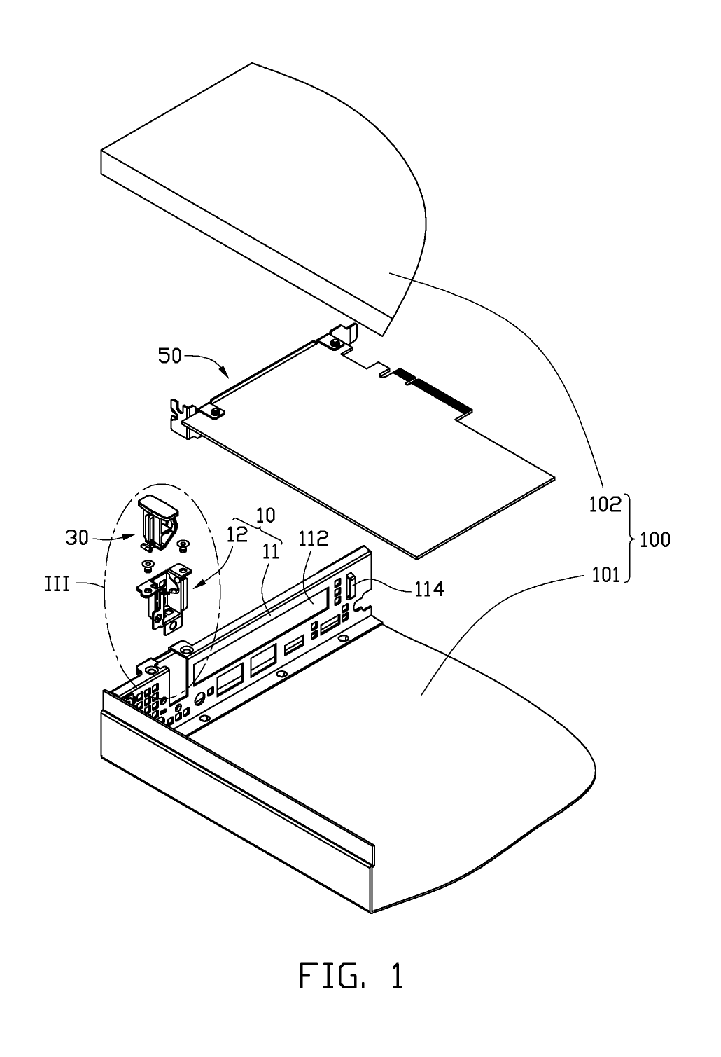

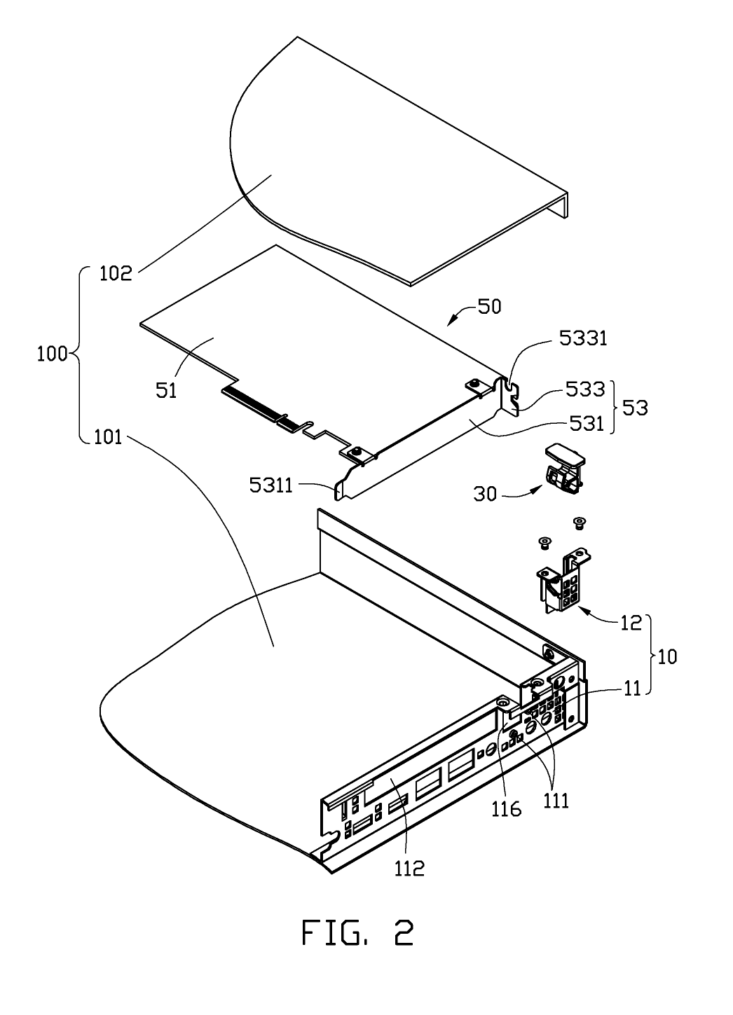

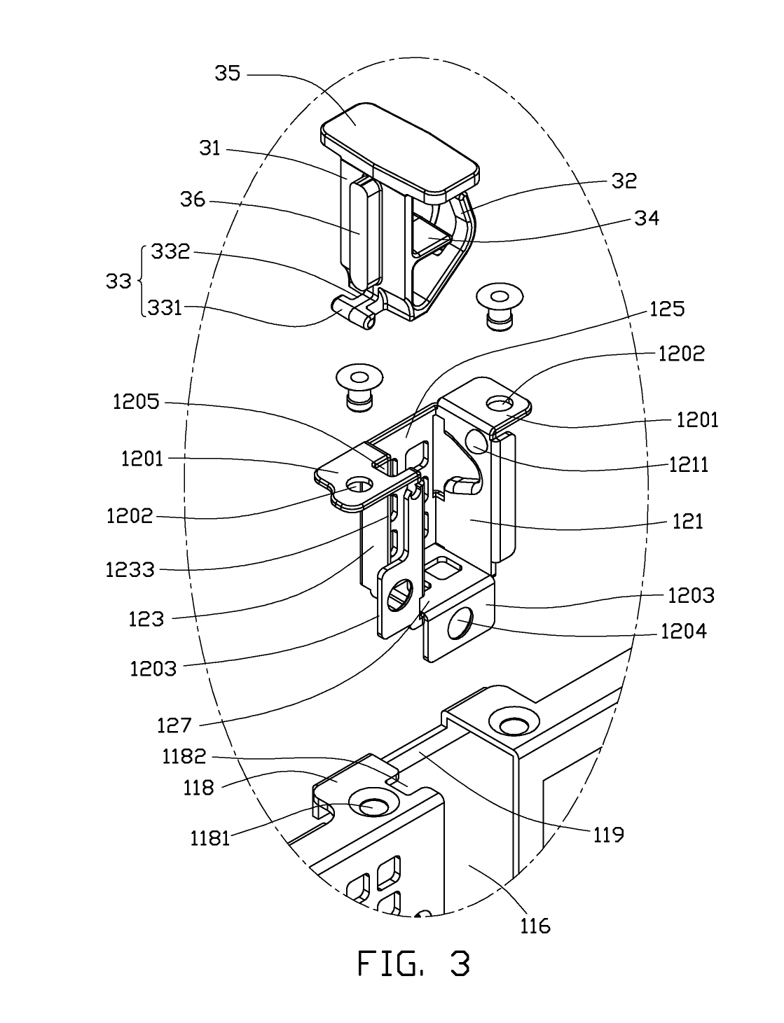

Referring to FIGS. 1-4, an embodiment of a mounting apparatus is used to fix an expansion card 50 to a chassis 100 of an electronic device. The mounting apparatus includes a locating member 10, and a locking member 30. The chassis 100 includes a housing 101 accommodating a motherboard (not shown), and a cover 102.

The expansion card 50 includes a circuit board 51 and an L-shaped block piece 53 fixed to one end of the circuit board 51. The block piece 53 includes a block portion 531 and a coupling portion 533 perpendicularly extending from one of two opposite ends of the block portion 531. A cutout 5331 is defined in the coupling portion 533. An inserting tongue 5311 extends from the other end of the block portion 531.

The locating member 10 includes a mounting plate 11 fixed to a rear end of the chassis 100, and a locating bracket 12. The mounting plate 11 defines an expansion slot 112. An arc-shaped holding portion 114 protrudes inwards from the mounting plate 11, and adjacent to one of the opposite ends of the expansion slot 112. An opening 116 is defined in the mounting plate 11 adjacent to the other end of the expansion slot 112, and extends up through a top of the mounting plate 11. Two mounting tabs 118 extend from the top of the mounting plate 11 adjacent to opposite sides of the opening 116, respectively. A reinforcing portion 119 is connected between the mounting tabs 118. Each of the mounting tabs 118 defines a fastening hole 1181. One of the mounting tabs 118 far away from the expansion slot 112 defines a notch 1182 communicating with the opening 116. Two securing columns 111 protrude out from the mounting plate 11, respectively below the opening 116 and adjacent to a side of the opening 116, away from the expansion slot 112.

The locating bracket 12 includes a first sidewall 121, a second sidewall 123 parallel to the first sidewall 121, a connection wall 125 connected between rear sides of the first and second sidewalls 121 and 123, and a bottom wall 127 connected between the bottoms of the first and second sidewalls 121 and 123. A bulge 1211 protrudes from a surface of the first sidewall 121 facing the second sidewall 123. The second sidewall 123 defines a lengthwise access slot 1231 extending in a direction perpendicular to the connection wall 125, and a slide slot 1233 communicating with the access slot 1231 and perpendicularly extending up from a middle of the access slot 1231. Two first attachment tabs 1201 respectively extend outwards from tops of the first and second sidewalls 121 and 123 away from each other. Each of the first attachment tabs 1201 defines an aligning hole 1202. A second attachment tab 1203 extends from a front side of the second sidewall 123 away from the first sidewall 121, and another second attachment tab 1203 extends downwards from a front side of the bottom wall 127. Each of the second attachment tabs 1203 defines an aligning hole 1204. The first attachment tabs 1201 on the top of the second sidewall 123 defines a cutout 1205 communicating with the slide slot 1233.

The locking member 30 is made of resilient material, such as rubber or plastic. The locking member 30 includes a base wall 31, an arc-shaped resilient pressing arm 32 extending up from a bottom end of the base wall 31, a lengthwise guiding block 36 protruding from a surface of the base wall 31 opposite to the pressing arm 32, a link portion 33 extending from lower portion of the surface of the base wall 31 opposite to the pressing arm 32, a position-limiting tab 34 extending from the base wall 31 and arranged between the base wall 31 and the pressing arm 32, and an abutting board 35 perpendicularly extending from the top end of the base wall 31. The link portion 33 is substantially T-shaped, and includes an abutting pole 331 parallel to the base wall 31, and a connection pole 332 connected between a middle of the abutting pole 331 and the base wall 31. A length of the abutting pole 331 is greater than a width of the slide slot 1233 of the locating bracket 12. A thickness of the connection pole 332 is greater than the width of the slide slot 1233.

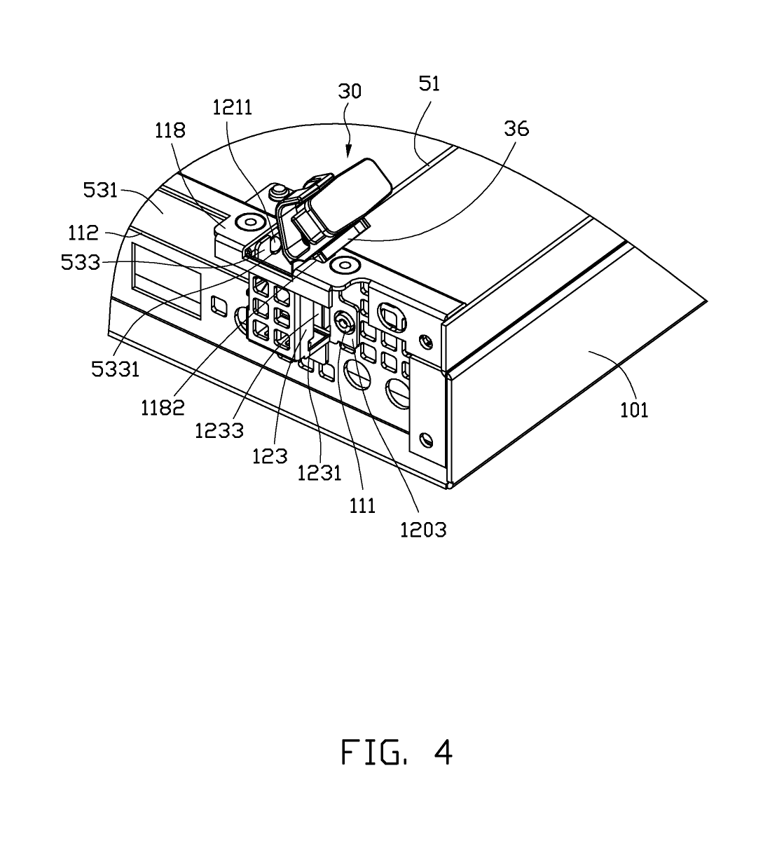

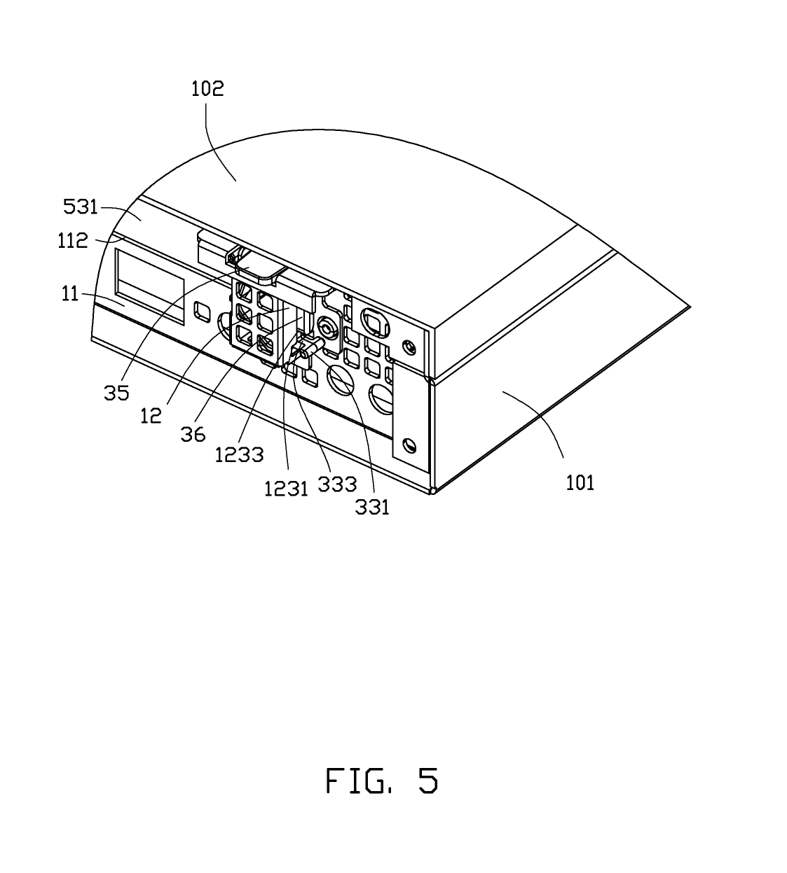

Referring to FIGS. 4 and 5, in assembly, the locating bracket 12 is attached to an outside of the mounting plate 11. The second attachment tabs 1203 abut the mounting plate 11. The securing columns 111 are fixedly received in the aligning holes 1204 of the corresponding second attachment tabs 1203. At the same time, the first attachment tabs 1201 correspondingly abut bottom sides of the mounting tabs 118 of the mounting plate 11. The aligning holes 1202 of the first attachment tabs 1201 align with the fastening holes 1181 of the corresponding mounting tabs 118. Two fasteners, such as screws or rivets, extend through the fastening holes 1181, and are fixed in the corresponding aligning holes 1202, to secure the locating bracket 12 to the mounting plate 11. The locating bracket 12 aligns with the opening 116 of the mounting plate 11. The cutout 1205 of the second sidewall 123 of the locating bracket 12 aligns with the notch 1182 of the mounting plate 11. The locking member 30 is manipulated to make the guiding block 36 slide into the slide slot 1233 through the notch 1182 of the mounting plate 11 and the cutout 1205 of the locating bracket 12. The link portion 33 is deformed by abutting the second sidewall 123 of the locating bracket 12. When the locking member 30 slides down to make the abutting pole 331 of the link portion 33 align with the access slot 1231 of the second sidewall 123, the link portion 33 is restored to make the abutting pole 331 pass through the access slot 1231, and the connection pole 332 align with the slide slot 1233.

Before mounting the expansion card 50, the locking member 30 is slid up to make the connection pole 332 slidably engage in the slide slot 1233. Since the length of the abutting pole 331 is greater than the width of the slide slot 1233, the abutting pole 331 cannot extend through the slide slot 1233, and the locking member 30 is prevented from disengaging from the locating bracket 12. The locking member 30 is further slid up, until the guiding block 36 slides out of the slide slot 1233 through the notch 1182 of the mounting plate 11 and the cutout 1205 of the locating bracket 12. The locking member 30 is rotated away from the opening 116 of the mounting plate 11 to enable the expansion card 50 to be mounted to the mounting plate 11.

To mount the expansion card 50 to the chassis 100, the expansion card 50 is manipulated to be electrically coupled to the motherboard. The block portion 531 of the block piece 53 shields the expansion slot 112 of the mounting plate 11. The inserting tongue 5311 engages between the mounting plate 11 and the holding portion 114. The coupling portion 533 is received in the locating bracket 12 and abuts the first sidewall 121. The bulge 1211 engages in the cutout 5331. The locking member 30 is manipulated to be received in the locating bracket 12, and is slid down. The guiding block 36 slides along the slide slot 1233, until the abutting board 35 abuts a top of the connection wall 125 of the locating bracket 12. The pressing arm 32 is deformed and presses the coupling portion 533 of the block piece 53 to tightly sandwich the coupling portion 533 between the pressing arm 32 and the first sidewall 121 of the locating bracket 12. Therefore, the block piece 53 is fixed to the mounting plate 11. The deformation of the pressing arm 32 is limited by the position-limiting tab 34, thereby preventing the pressing arm 32 from being damaged. The cover 102 is covered on the housing 101 and abuts the abutting board 35 to prevent the locking member 30 from moving up to release the block piece 53 of the expansion card 50.

Even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A mounting apparatus for mounting an expansion card with a block piece to a chassis, the block piece comprising a block portion and a coupling portion perpendicularly extending from an end of the block portion, the mounting apparatus comprising:
a locating member comprising a mounting plate for being fixed to a rear end of the chassis, and a locating bracket secured to the mounting plate, the mounting plate abutting the block portion of the expansion card, and defining an opening, the locating bracket aligning with the opening and receiving the coupling portion of the expansion card; and
a locking member slidably received in the locating bracket and comprising a pressing arm pressing the coupling portion to fix the coupling portion to the locating bracket.

2. The mounting apparatus of claim 1, wherein the locating bracket comprises a first sidewall and a second sidewall parallel to each other, and respectively adjacent to opposite sides of the opening of the mounting plate, the locking member is slidably connected to the second sidewall, the pressing arm of the locking member and the first sidewall sandwiches the coupling portion of the expansion card.

3. The mounting apparatus of claim 2, wherein the locking member further comprises a base wall connected to an end of the pressing arm, and a link portion extending from the base wall, the second sidewall of the locating bracket defines a slide slot extending down from a top of the second sidewall, the link portion is substantially T-shaped, and comprises an abutting pole and a connection pole connected between a middle of the abutting pole and the base wall, a lengthwise direction of the abutting pole is perpendicular to a lengthwise direction of the slide slot, a length of the abutting pole is greater than a width of the slide slot, a thickness of the connection pole is greater than the width of the slide slot.

4. The mounting apparatus of claim 3, wherein the link portion is adjacent to a bottom of the base wall of the locking member, the locking member further comprises a guiding block protruding from the base wall above the link portion, and slidably received in the slide slot.

5. The mounting apparatus of claim 4, wherein a tab extends from a top of the second sidewall of the locating bracket away from the first sidewall, and defines a cutout communicating with the slide slot for accessing of the guiding block into the slide slot.

6. The mounting apparatus of claim 3, wherein the pressing arm is arc-shaped, the locking member further comprises a position-limiting tab extending from the base wall and arranged between the base wall and the pressing arm.

7. The mounting apparatus of claim 1, wherein the locking member is made of rubber or plastic.

8. An electronic device, comprising:
a chassis comprising a housing and a cover mounted on the housing;
a locating member comprising a mounting plate fixed to a rear end of the housing, and a locating bracket secured to the mounting plate, the mounting plate defining an opening, the locating bracket aligning with the opening; and
an expansion card comprising a circuit board and a substantially L-shaped block piece fixed to one end of the circuit board, the block piece comprising a block portion abutting the mounting plate, and a coupling portion perpendicularly extending from one of two opposite ends of the block portion through the opening of the mounting plate, and received in the locating bracket; and
a locking member slidably received in the locating bracket and comprising a pressing arm pressing the coupling portion to fix the coupling portion to the locating bracket.

9. The electronic device of claim 8, wherein the locking member further comprise an abutting board connected to a top of the base wall, the cover of the chassis abuts the abutting board.

10. The electronic device of claim 8, wherein the mounting plate further defines an expansion slot, an arc-shaped holding portion protrudes from the mounting plate adjacent to an end of the expansion slot, the block piece of the expansion card comprises an inserting tongue extends from the other end of the block portion, and engaged between the holding portion and the mounting plate.

11. The electronic device of claim 8, wherein the locating bracket comprises a first sidewall and a second sidewall parallel to each other, and respectively adjacent to opposite sides of the opening of the mounting plate, the locking member is slidably connected to the second sidewall, the block piece of the expansion card is sandwiched between the pressing arm of the locking member and the first sidewall.

12. The electronic device of claim 11, wherein the locking member further comprises a base wall connected to an end of the pressing arm, and a link portion extending from the base wall, the second sidewall of the locating bracket defines a slide slot extending down from a top of the second sidewall, the link portion is substantially T-shaped, and comprises an abutting pole and a connection pole connected between a middle of the abutting pole and the base wall, a lengthwise direction of the abutting pole is perpendicular to a lengthwise direction of the slide slot, a length of the abutting pole is greater than a width of the slide slot, a thickness of the connection pole is greater than the width of the slide slot.

13. The electronic device of claim 12, wherein the link portion is adjacent to a bottom of the base wall of the locking member, the locking member further comprises a guiding block protruding from the base wall above the link portion, and slidably received in the slide slot.

14. The electronic device of claim 13, wherein a tab extends from a top of the second sidewall of the locating bracket away from the first sidewall, and defines a cutout communicating with the slide slot for accessing of the guiding block into the slide slot.

15. The electronic device of claim 12, wherein the pressing arm is arc-shaped, the locking member further comprises a position-limiting tab extending from the base wall and arranged between the base wall and the pressing arm.

16. The electronic device of claim 11, wherein the coupling portion of the block piece of the expansion card defines a notch, a bulge protrudes from the first sidewall of the locating bracket, and engages in the notch of the coupling portion.

17. The electronic device of claim 8, wherein the locking member is made of rubber or plastic.
